(19) United States
(12) Patent Application Publication
(10) Pub. No.: US 2003/0030574 A1
(43) Pub. Date: Feb. 13, 2003

(54) Control circuit for multimedia keyboards

(76) Inventor: Shu-Yi Chien, Taipei (TW)

Correspondence Address: Alan D. Kamrath, Rider, Bennett, Egan & Arundel, LLP, 333 South Seventh Street, Suite 2000, Minneapolis, MN, 55402, US

(21) Appl. No.: 10/101,128

(22) Filed: Mar. 19, 2002

(30) Foreign Application Priority Data
Aug. 10, 2001 (TW) 090213635

(51) Int. Cl. H03M 11/00

(52) U.S. Cl. 341/22

(57) ABSTRACT

A control circuit for multimedia keyboards comprises a microprocessor and a key-scan array, wherein the key-scan array is formed by a basic matrix plus an expanded matrix. The basic matrix is used to save input key codes for key scanning. The circuit design is characterized in that an expanded matrix is added to create expanded multimedia functions or hot keys on a keyboard. The data and I/O lines of the expanded matrix are connected to the extra data pins of the microprocessor not previously used by the basic matrix. In the conventional method, an extra I/O line is used to create the multimedia keys, having many disadvantages including slow key scan rate, complicated control program and increased manufacturing costs. Through the specially designed control circuit for multimedia keyboards, all the earlier problems can be obviated.

### BACKGROUND OF THE INVENTION

1. Field of the Invention

The present invention relates to a control circuit for multimedia keyboards, in particular, to providing of a control circuit that supports a multimedia keyboard with expanded function keys without having to use extra I/O lines on the microprocessor.

2. Description of Related Art

A keyboard is a basic input device for inputting data to a computer. The physical appearance of a standard keyboard has gone through several stages of transformation, which is closely related to the development of operation systems for computers. The most obvious change in the appearance every time a new version is developed is that number of keys on a keyboard has increased. The earliest computer keyboard was built for an IBM XT™ with 81 keys; later came the AT™ series with 101 keys; and then the Windows™-based operating system Windows 95 ™ was launched employing 104 keys; Windows 98™ operating system with 107 keys; and, at present, Windows 2000™ with 125 keys. This expansion course was in part to reflect the constant upgrading of functionality in our computer operating systems. With more special function keys, computer users are able to use the expanded functions created in newer versions of operating systems. When the computer operating system is adapted to a Windows™-based user interface, an electronic mouse in addition to the conventional keyboard has become a standard feature for personal computers (PC), as the basic input device. In the past few years, PC users would only need a 104 key keyboard and a mouse to work with a Windows™-based operating system. However, Windows 2000™ has significantly changed the situation, because major enhancements have been made in multimedia and Internet applications. A new keyboard has been designed with many built-in hot keys, such as Internet dial up, next page scrolling, play multimedia, pause, next track, previous track, eject etc. If a PC user still wants to use a 104 key keyboard and a mouse to work with Windows 2000™, he or she will miss out many of the multimedia and Internet functions that are designed to enhance the operation efficiency of a computer user. According to the latest keyboard specifications released by Microsoft™, a total of 125 keys are supported by Windows 2000™ or newer versions of the operating system, which is a big increase when compared with 104 keys for Windows 95™ and 107 keys for Windows 98™.

In a standard keyboard, the number of key codes that are supported by the hardware is 128 (represented by a 8×16 matrix), less certain language specific keys and system control keys, the maximum number of key codes available for use as hot keys is eight or less. Therefore, any attempt to increase hot keys by fifteen or more is simply beyond the existing limits.

A method has been previously proposed to solve the above-mentioned problem by adding another I/O line to expand the function keys on a conventional keyboard. By doing so, the original 8×16 matrix has to be changed to become a 9×16 matrix. An extra I/O line can support 16 additional key codes, which could be used for expanded function keys.

In general, current microprocessors can read eight bits of data at a time, and that is why the key-scan codes for a standard keyboard matrix are designed with 8×16 matrix structure, wherein the first number represents a total of eight I/O lines, and the second number represents a total of sixteen data lines. In a read operation, the microprocessor scans all I/O lines in one operation cycle. However, if using another I/O line in the key code matrix as proposed in the previous method, the microprocessor would not be able to scan all I/O lines in one cycle. It would need two machine cycles to complete a data read for all I/O lines. Under such condition, the scan operation has to be slowed down, the control program in the processor has to be modified with increased complexity, and more memories are needed for the read operation. In the normal system configuration with a conventional keyboard, the memory size in a microprocessor is still adequate to handle the extra burden caused by the extra I/O line. But when the communication between the keyboard and the computer system is changed to wireless means, the existing memory size is no longer adequate to support the advanced applications. The memory size therefore has to be expanded, thus raising the manufacturing costs for the product.

From the foregoing, by solving the problem of inadequate key codes, the previously mentioned method has made the internal control program of the microprocessor more complicated to write, and has consumed more memory resources with higher costs. The present invention is intended to solve all the problems mentioned above.

### SUMMARY OF THE INVENTION

The main objective of the present invention is to provide a control circuit that supports the expanded multimedia keys on a keyboard without having to use additional I/O lines.

The control circuit in accordance with the current embodiment comprises:

a microprocessor with eight I/O pins and sixteen or more data pins;

a key-scan array which is formed by a basic matrix plus an expanded matrix, wherein:

the data and I/O lines of the basic matrix are connected to the corresponding data and I/O pins of the microprocessor, allowing the microprocessor to read the keystrokes saved in the base matrix;

the data and I/O lines of the expanded matrix are connected to the extra data pins of the microprocessor, not used by the base matrix, for creating multiple multimedia function keys or hot keys;

Using the above-mentioned expanded matrix, the present invention is able to satisfy the needs for expansion of hot keys. Since the present design has not used any extra I/O line, the problems with double scanning, software programming, and increased manufacturing costs are obviated completely.

The above-mentioned base matrix has a total of eight I/O lines and sixteen data lines.

The above-mentioned expanded matrix has a total of eight I/O lines and N data lines; where N is a number more than two. The data lines are respectively connected to the extra data pins on the microprocessor, whereby eight more keys are created with each additional data line.

Other objectives, advantages, and novel features of the invention will become apparent from the detailed description when taken in conjunction with the attached drawings

### BRIEF DESCRIPTION OF THE DRAWINGS

FIG. 1 is a circuit diagram of the control circuit in accordance with the present invention.

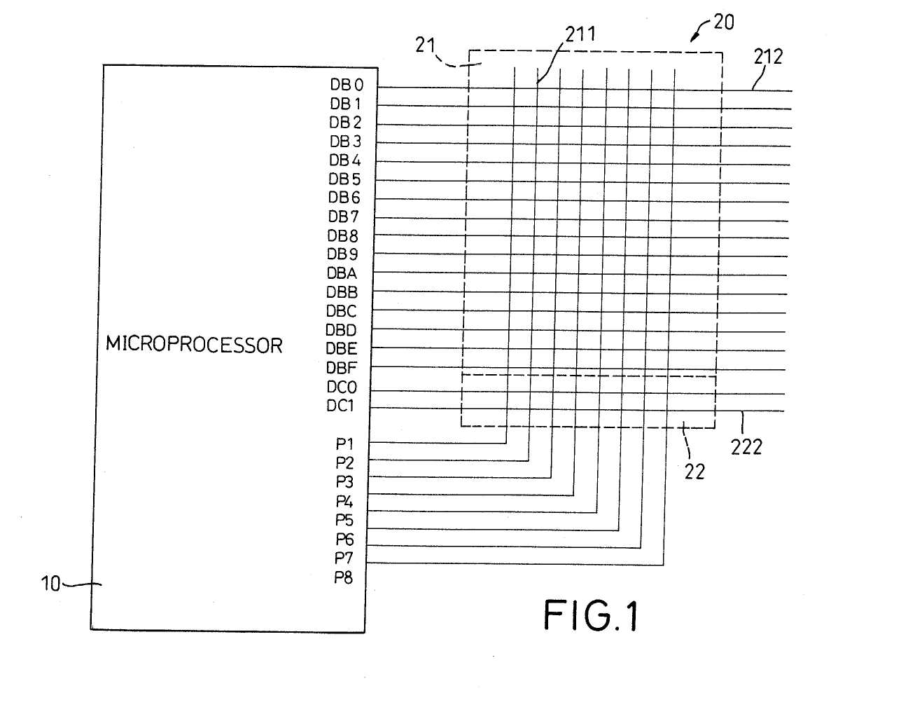

### DETAILED DESCRIPTION OF THE PREFERRED EMBODIMENT

The control circuit for multimedia keyboards comprises:

a microprocessor (10) with a total of eight I/O pins (P1-P8) and sixteen or more data pins (DB0-DBF); and

a key-scan array (20) which is formed by a basic matrix (21) plus an expanded matrix (22).

The above-mentioned microprocessor (10) in accordance with the current embodiment has a total of eighteen data pins (DB0-DBF, DC0, DC1), but the current pin number is only used for the purpose of illustration, and is not in any way intended to be a requirement for the present invention.

The above-mentioned base matrix (21) has a total of eight I/O lines (211) and sixteen data line (212) representing a standard matrix formation, wherein the I/O lines (211) and data lines (212) are connected respectively to corresponding data pins (DB0-DBF) and I/O pins (P1-P8). The microprocessor (10) can then read the keystrokes saved in the base matrix (21).

The expanded matrix (22) has a total of eight I/O lines (211) and two or more data lines (222), wherein the I/O lines (211) are the same as those used in the base matrix (21), but two or more data lines (222) are created in addition to those already existing. In the current embodiment, two data lines (222) are used to match against the two additional data pins (DC0, DC1) on the microprocessor (10) as mentioned earlier. Basing on the structure of a matrix with an 8×N format, each additional data line (222) is able to create eight additional keys; that means the expanded matrix (22), as in the current embodiment, provides a total of sixteen hot keys to support various multimedia control functions. If more data lines (222) are used, there will be even more key codes available for possible expansion of hot keys.

From the foregoing, the use of expanded matrix in the circuit design as in the present invention can satisfy the needs for expansion of hot keys. The present invention claims to have produced a multimedia keyboard with expandable function keys while obviating the earlier problems.

Normal scanning rate maintained: In the present invention the number of I/O lines is eight, the same as in the original matrix. When the microprocessor reads the key-scan matrix, all I/O lines can be scanned in one operation cycle. The increase in data lines has no effect on the scanning rate; therefore the scanning rate shall be faster than that using the conventional method.

No extra memory: The internal control program in the microprocessor does not need extra memory space for performing the second scan over the remaining key codes.

No burden for software programming: Since the microprocessor does not need to perform a second scan over the remaining I/O lines, the internal control program for the microprocessor is minimally affected. The program development costs and the overall manufacturing costs therefore can be well controlled.

What is claimed is:

1. A control circuit for multimedia keyboards, the control circuit comprising:
a key-scan array formed by a base matrix and an expanded matrix; and
a microprocessor which has a regular number of I/O pins and data pins for connection to the base matrix, while a quantity of extra data lines are connected to the expanded matrix to satisfy the system requirements for additional keys used to support multimedia applications.

2. A control circuit for multimedia keyboards as claimed in claim 1, wherein the data lines of the expanded matrix are connected to the extra data pins not used by the base matrix, used for expansion of function keys or hot keys on a multimedia keyboard.

3. A control circuit for multimedia keyboards as claimed in claim 1, wherein the base matrix has a total of eight I/O lines and sixteen data lines disposed in a matrix format.

4. A control circuit for multimedia keyboards as claimed in claim 2, wherein the base matrix has a total of eight I/O lines and sixteen data lines disposed in a matrix format.

5. A control circuit for multimedia keyboards as claimed in claim 1, wherein the expanded matrix has a total of eight I/O lines and two or more data lines disposed in a matrix format.

6. A control circuit for multimedia keyboards as claimed in claim 2, wherein the expanded matrix has a total of eight I/O lines and two or more data lines disposed in a matrix format.
